(19) United States
(12) Patent Application Publication
(10) Pub. No.: US 2024/0035140 A1
(43) Pub. Date: Feb. 1, 2024

(54) RARE EARTH OXIDE THERMAL SPRAYING MATERIAL AND PRODUCING METHOD THEREOF, AND RARE EARTH OXIDE THERMAL SPRAYED FILM AND FORMING METHOD THEREOF

(71) Applicant: Shin-Etsu Chemical Co., Ltd., Tokyo (JP)

(72) Inventors: Ryusei Nishimura, Echizen-shi (JP); Yasushi Takai, Tokyo (JP); Hajime Nakano, Echizen-shi (JP); Kouhei Miyamoto, Echizen-shi (JP)

(73) Assignee: Shin-Etsu Chemical Co., Ltd., Tokyo (JP)

(21) Appl. No.: 18/257,607

(22) PCT Filed: Dec. 16, 2021
(86) PCT No.: PCT/JP2021/046404

§ 371 Date: Jun. 15, 2023

(30) Foreign Application Priority Data
Dec. 22, 2020 (JP) 2020-211928

(51) Int. Cl. C23C 4/11

(52) U.S. Cl. CPC C23C 4/11; C23C 4/134

(57) ABSTRACT

Provided is a rare earth oxide thermal spraying material which has a granular form having a volume-based average particle diameter D50 of 10 μm to 18 μm inclusive as measured by a laser diffraction scattering method, a compression degree of 13 or less and a BET specific surface area of 0.1 m²/g to 2 m²/g inclusive. The rare earth oxide thermal spraying material according to the present invention can form a dense thermally sprayed film having a small porosity even by atmospheric plasma spraying in which a thermal spraying material is supplied in a solid (particle) form. When a thermally sprayed film is formed by atmospheric plasma spraying using the rare earth oxide thermal spraying material according to the present invention, it becomes possible to form the thermally sprayed film in a curved shape easily and to form the thermally sprayed film in a large thickness.

### TECHNICAL FIELD

The present invention relates to a rare earth oxide thermal spraying material, and a producing method thereof, and a rare earth oxide thermal sprayed film and a forming method thereof.

### BACKGROUND ART

In etcher steps of display manufacturing and semiconductor manufacturing, an object to be treated is processed in halogen-based gas plasma atmosphere having high corrosivity. Thus, for parts that contact with the halogen-based gas plasma in an etcher apparatus, members in which a thermal sprayed film having excellent corrosion resistance is formed on the surface of metal aluminum or aluminum oxide ceramics by thermal spraying yttrium oxide or yttrium fluoride are adopted (JP-A-2002-302754 (Patent Document 1), JP-A-2002-080954 (Patent Document 2), JP-A-2002-115040 (Patent Document 3)). As halogen-based corrosive gases used in the etcher step of semiconductor manufacturing, SF₆, CF₄, CHF₃, ClF₃, HF and others, as fluorine-based gases, and Cl₂, BCl₃, HCl and others, as chlorine-based gases, are used.

Yttrium oxide-coated parts which are produced by atmospheric plasma spraying of yttrium oxide have fewer technical problems and have been put to practical use as thermal sprayed members for semiconductor manufacturing from early on. On the other hand, although an yttrium fluoride thermal sprayed film is excellent in corrosion resistance, the yttrium fluoride thermal sprayed film has technical problems in atmospheric plasma spraying of yttrium fluoride such that when the yttrium fluoride passes through a flame at not less than 3,000° C. and melts, the fluoride decomposes, and partially becomes a mixture of fluoride and oxide, therefore, practical use is behind compared to thermal sprayed members in which the oxide is formed. Further, yttrium oxyfluoride has been proposed to compensate for the problems of yttrium oxide and yttrium fluoride (JP-A-2014-009361 (Patent Document 4)).

In JP-A-2015-227512 (Patent Document 5), improve of corrosion resistance by reducing a porosity of the yttrium oxide film is studied. Specifically, as a forming method of a film having a low porosity, suspension thermal spraying is studied. In atmospheric plasma spraying, a film is formed with a material having an average particle size of 20 μm to 50 μm, while in suspension thermal spraying, a dense film having a low porosity is realized by suppling a material having an average particle size of 0.1 to 10 μm which has poor flowability by a slurry.

### PRIOR ART DOCUMENTS

### Patent Documents

Patent Document 1: JP-A 2002-302754

Patent Document 2: JP-A 2002-080954

Patent Document 3: JP-A 2002-115040

Patent Document 4: JP-A 2014-009361

Patent Document 5: JP-A 2015-227512

### SUMMARY OF INVENTION

### Technical Problem

Yttrium oxyfluoride as described in JP-A-2014-009361 has problems that the yttrium oxyfluoride is easy to decompose during thermal spraying, and it is difficult to form a dense thermal sprayed film. A dense film having low porosity is obtained according to suspension thermal spraying as described in JP-A-2015-227512. However, suspension thermal spraying has problems such as difficulty in forming on a curved surface and difficulty in forming a thick film.

A dense thermal sprayed film having low porosity has high corrosion resistance to highly corrosive halogen-based gases, thus, if smaller particles can be supplied even in atmospheric plasma spraying in which a thermal spraying material is supplied in the form of solid (particles), even if it is not suspension thermal spraying, a thermal sprayed film that is dense and has a low porosity is formed, it is possible to form such a thermal sprayed film on a curved surface and to form the thermal sprayed film thick.

The present invention was carried out in view of the above circumstances, and an object of the present invention is to provide a rare earth oxide thermal spraying material that has a higher fluidity although has a smaller particle size, compared with a conventional thermal spraying material, and that can be thermally sprayed even by a normal thermal spraying apparatus, a producing method thereof, a rare earth oxide thermal sprayed film that is formed with using a rare earth oxide thermal sprayed material, and a forming method of a rare earth oxide thermal sprayed film.

### Solution to Problem

In order to achieve the above-described object, the inventors have conducted earnestly investigations, and as a result, the inventors found that: a rare earth oxide thermal spraying material that has a volume-based average particle size D50 by a laser diffraction/scattering method of not less than 10 μm and not more than 18 μm, a compression degree of not more than 13, and a BET specific surface area of not less than 0.1 m²/and not more than 2 m²/g has a higher fluidity although has a smaller particle size; and that, when this is used as a thermal spraying material, even by atmospheric plasma spraying, it is possible to form a dense thermal sprayed film having low porosity and to form a thick thermal sprayed film, and then the present invention has been completed.

Accordingly, the present invention provides a rare earth oxide thermal spraying material and a producing method thereof, and a rare earth oxide thermal sprayed film and a forming method thereof, as follows.
1. A rare earth oxide thermal spraying material having a volume-based average particle size D50 by a laser diffraction/scattering method of not less than 10 μm and not more than 18 μm, a compression degree of not more than 13, and a BET specific surface area of not less than 0.1 m²/g and not more than 2 m²/g.
2. The rare earth oxide thermal spraying material according to 1, wherein, in a pore volume distribution measured by a mercury intrusion method, the pore volume distribution has a first peak within a range of pore diameter of 1 μm to 10 μm, and a second peak within a range of pore diameter of less than 1 μm, and a ratio (P2/P1) of a cumulative pore volume (P2) within a range of pore diameter of 0.1 μm to 1 μm to a cumulative pore volume (P1) within a range of pore diameter of 1 μm to 10 μm is not less than 0.05 and not more and 0.3.
3. The rare earth oxide thermal spraying material according to 1 or 2, wherein a crystallite size calculated from a peak of a rare earth oxide measured by X-ray diffraction is not less than 1 μm.
4. The rare earth oxide thermal spraying material according to any one of 1 to 3, wherein a rare earth element constituting the rare earth oxide comprises at least one selected from yttrium (Y), gadolinium (Gd), holmium (Ho), erbium (Er), ytterbium (Yb) and lutetium (Lu).
5. A producing method of a particulate rare earth oxide thermal spraying material having a volume-based average particle size D50 by a laser diffraction/scattering method of not less than 10 μm and not more than 18 μm, comprising:
   a step for preparing a slurry comprising rare earth oxide particles and a dispersion medium;
   a step for obtaining granulated particles in which the rare earth oxide particles are agglomerated from the slurry;
   a step for firing the granulated particles at a temperature of not less than 1400° C. and not more than 1600° C.; and
   a step for holding the granulated particles after firing under an atmosphere having a temperature of not less than 2,400° C. and not more than 3,900 for not less than 0.1 second to melt at least a surface portion of each of the granulated particles after firing, and then taking out from the atmosphere and cooling.
6. A rare earth oxide thermal sprayed film which is formed by atmospheric plasma spraying with using the rare earth oxide thermal spraying material according to any one of 1 to 4, and has a porosity of not more than 1%.
7. A forming method of a rare earth oxide thermal sprayed film, comprising forming by atmospheric plasma spraying with using the rare earth oxide thermal spraying material according to any one of 1 to 4.
8. The forming method according to 7, wherein a rare earth oxide thermal sprayed film having a porosity of not more than 1% is formed.

### Advantageous Effects of Invention

The rare earth oxide thermal spraying material of the present invention can form a dense thermal sprayed film having low porosity even by atmospheric plasma thermal spraying in which the thermal spraying material is supplied in the form of solid (particles). Further, by forming a thermal sprayed film by atmospheric plasma spraying with using the rare earth oxide thermal spraying material of the present invention, the thermal sprayed film can be easily formed on a curved surface, and the thermal sprayed film can be formed thick.

### BRIEF DESCRIPTION OF DRAWINGS

FIG. 1 It is a scanning electron microscope image of particles of the thermal spraying material in Example 1 before surface flattening treatment.

FIG. 2 It is a scanning electron microscope image of particles of the thermal spraying material in Example 1 after surface flattening treatment.

FIG. 3 It is a chart showing a particle size distribution of the thermal spraying material in Example 1 before surface flattening treatment.

FIG. 4 It is a chart showing a particle size distribution of the thermal spraying material in Example 1 after surface flattening treatment.

FIG. 5 It is a chart showing a pore volume distribution of the thermal spraying material in Example 2.

FIG. 6 It is a scanning electron microscope image of a cross section of the thermal sprayed film in Example 1.

FIG. 7 It is a scanning electron microscope image of a cross section of the thermal sprayed film in Comparative Example 1.

FIG. 8 It is a scanning electron microscope image of a cross section of the thermal sprayed film in Example 2.

FIG. 9 It is a scanning electron microscope image of a cross section of the thermal sprayed film in Comparative Example 2.

FIG. 10 It is a chart showing a distribution of gray value of a scanning electron microscope image of a cross section of the thermal sprayed film in Example 1.

### DESCRIPTION OF EMBODIMENTS

The present invention is described in detail below.

he thermal spraying material of the present invention is a rare earth oxide thermal spraying material. This rare earth oxide thermal spraying material contains a rare earth element (R) and oxygen (O), and preferably consists essentially of the rare earth element and oxygen, however, elements other than the rare earth elements and oxygen are permissibly contained as long as their contents are impurity amounts. The rare earth oxide is preferably a trivalent oxide represented by R₂O₃.

The rare earth oxide thermal spraying material of the present invention is particulate, and has a volume-based average particle size D50 (median diameter, cumulative 50% particle diameter) by a laser diffraction/scattering method of not more than 18 μm, preferably not more than 16 μm. Also, the average particle size D50 is preferably not less than 10 μm, more preferably not less than 12 μm. In addition, in measuring a particle size distribution by the laser diffraction/scattering method, in some cases, the measurement sample is subjected to a dispersion treatment such as ultrasonic irradiation (for example, at an output of 40 W for 3 minutes, at an output 300 W for 15 minutes, or others), however, since the particle size of the rare earth oxide thermal spraying material of the present invention scarcely change even when such ultrasonic irradiation is performed, the measurement sample may or may not be subjected to dispersion treatment such as ultrasonic irradiation in measuring the particle size distribution.

The rare earth oxide thermal spraying material of the present invention preferably has a sharp particle size distribution. Specifically, a dispersion index represented by (D90−D10)/(D90+D10) is preferably not more than 0.5. The lower limit of the dispersion index is usually not less than 0.2, however, is not particularly limited. Also, a maximum particle size D100 is preferably not more than 65 μm. The lower limit of the maximum particle size D100 is usually not less than 40 μm, however, is not particularly limited. Here, D10, D90 and D100 are, respectively, a volume-based cumulative 10% particle size, a cumulative 90% particle size and a cumulative 100% particle size in particle size distribution by a laser diffraction/scattering method.

A rare earth oxide thermal spraying material generally have good fluidity when a compression degree is not more than 15, and conversely, when the compression degree is not less than 20, the fluidity is poor. The fluidity of the rare earth oxide thermal spraying material is determined by a difference or ratio between a tap density and a bulk density in sparse packing, depending on the particle size distribution and the shape of particles. The rare earth oxide thermal spraying material of the present invention has a compression degree of preferably not more than 13, more preferably not more than 12. Specifically, the compression degree is obtained by the following expression:

Compression degree (%)=(Tap density−Bulk density in sparse packing)/Tap density×100.

In addition, an angle of repose is known as an index of fluidity determined by the shape or friction of particle surface, and the angle of repose of the rare earth oxide thermal spraying material of the present invention is preferably not more than 33°, more preferably not more than 30°.

The rare earth oxide thermal spraying material of the present invention has a BET specific surface area of preferably not less than 0.1 m²/g, more preferably not less than 0.3 m²/g. Also, the BET specific surface area is preferably not more than 5 m²/g, more preferably not more than 3.5 m²/g.

In order to obtain good fluidity, the rare earth oxide thermal spraying material of the present invention preferably has a more nearly spherical shape. Therefore, an aspect ratio represented by a ratio of a major axis and a minor axis of the outer shape of particles is preferably not more than 2, more preferably not more than 1.2. When the aspect ratio is within such a range, better fluidity is likely to be obtained.

When a pore volume of the rare earth oxide thermal spraying material of the present invention is measured by a mercury intrusion method, normally, a pore diameter distribution which includes two peaks of pores derived from gaps between particles and pores derived from recesses on the particle surface is obtained. As the peak of pore diameter derived from gaps between particles, it is preferable to have a first peak within a range of ⅓ to ½ of the average particle size D50, specifically, within a pore diameter within a range of 1 μm to 10 μm. The first and second peaks are usually peaks having a width, and may be peaks having the peak top within the above-described predetermined range, respectively. When the peak of pore diameter derived from the gaps between particles is sharp, the particle size distribution is also sharp, and when the peak of pore diameter derived from the gaps between particles is broad, the particle size distribution is also broad. On the other hand, as the peak of pore diameter derived from recesses on the particle surface, it is preferable to have a second peak within a range of less than 1 μm. A small second peak means few pores derived from recesses on the surface, and the small second peak is preferable.

In the rare earth oxide thermal spraying material of the present invention, it is preferable that in the pore diameter distribution, a low ratio (P2/P1) of a cumulative pore volume (P2) within a range of pore diameter of 0.1 μm to 1 μm in which pores derived from recesses on the particle surface are mainly included to a cumulative pore volume (P1) within a range of pore diameter of 1 μm to 10 μm in which pores derived from gaps between particles are mainly included. The cumulative pore volume is the sum of pore volumes over the whole of a predetermined pore diameter range. Specifically, P2/P1 is preferably not more than 0.3, more preferably not more than 0.25. Particles having a small average particle size and a large BET specific surface area tend to have low fluidity, however, good fluidity can be obtained even they are particles having a small average particle size and a large BET specific surface area since the lower the P2/P1, the narrower the width of the particle size distribution and the less irregularities on the particle surface. On the other hand, the lower limit of P2/P1 is usually not less than 0.05, particularly not less than 0.1, however, is not particularly limited.

When a rare earth oxide thermal sprayed film is formed with using a rare earth oxide thermal spraying material having a sufficiently large crystal grain size as the rare earth oxide thermal spraying material, a film having a low porosity can be obtained. The rare earth oxide thermal spraying material of the present invention has a crystallite size calculated from a peak of a rare earth oxide measured by X-ray diffraction of not less than 1 μm, more preferably not less than 5 μm. When the crystallite size, which has a positive correlation with the crystal grain size, is within the above-described range, it can be said that the crystal grain size is sufficiently large.

Whole-Powder-Pattern Decomposition method (WPPD method) can be applied to the evaluation of crystallite size by X-ray diffraction measurement. In this method, the entire within 2θ=10 to 70° of the X-ray diffraction pattern is targeted, and matching is performed with the pure content (standard sample) of all the components constituting the sample to be examined, and according to the results, the crystallite size is calculated. Evaluation of crystallite size by X-ray diffraction is evaluation of the size of crystal in a solid from the peak obtained by X-ray diffraction, and according to Scherrer equation, the half width of the diffraction peak becomes narrower when the crystallite size becomes larger. Therefore, in this method, it is generally considered that sufficient accuracy cannot be obtained when the crystallite size is not less than 0.1 μm, however, for the rare earth oxide thermal spraying material of the present invention, it is sufficient that the crystallite size which is calculated from the peak of the rare earth oxide measured by X-ray diffraction is evaluated to be within a predetermined range, and by forming a rare earth oxide thermal sprayed film with using a rare earth oxide thermal spraying material that has been evaluated to have a crystallite size within a predetermined range, a film having a lower porosity can be formed.

The rare earth element constituting the rare earth oxide thermal spraying material is preferably at least one selected from yttrium (Y), gadolinium (Gd), holmium (Ho), erbium (Er), ytterbium (Yb) and lutetium (Lu). In addition, heavy rare earth elements have a smaller ionic radius and higher thermal stability, however, are more expensive. Under consideration of economic efficiency, use of at least one selected from yttrium (Y), holmium (Ho) and erbium (Er) can suppress a refining cost, thus, is advantageous.

The rare earth oxide thermal spraying material of the present invention can be produced by, for example, a method including
a step for preparing a slurry including rare earth oxide particles and a dispersion medium;
a step for obtaining granulated particles in which the rare earth oxide particles are agglomerated from the slurry;
a step for firing the granulated particles at a temperature of not less than 1400° C. and not more than 1600° C.; and
a step for holding the granulated particles after firing under an atmosphere having a temperature of not less than 2,400° C. and not more than 3,900 for not less than 0.1 second to melt at least a surface portion of each of the granulated particles after firing, and then taking out from the atmosphere and cooling (a surface flattening treatment step).

For preparing the slurry, rare earth oxide particles having an average particle size D50 of not more than 1.5 μm may be used. Water is preferable as the dispersion medium. An organic compound such as carboxymethylcellulose may be added as a binder into the slurry, as needed. The granulated particles can be obtained by granulating the slurry by a granulating apparatus such as a spray dryer. The resulting granulated particles are fired, for example, at a temperature of not less than 1400° C. and not more than 1600° C. in the atmosphere. The granulated particles after firing are preferably classified so as to have an average particle size D50 of not more than 18 μm, as needed.

The granulated particles obtained by firing have irregular surfaces as they are, and are poor in fluidity. In order to improve fluidity, it is necessary to reduce irregular surfaces to increase a bulk density. A melting points of rare earth oxides differ depending on the rare earth elements, and for example, yttrium oxide has a melting point of 2,410° C. and erbium oxide has a melting point of 2,355° C. By performing a treatment (surface flattening treatment) in which the granulated particles after firing are held in an atmosphere at a temperature of not less than 2,400° C. and not more than 3,900° C., which is around the melting point of the rare earth oxide, for not less than 0.1 second, at least the surface portion of each of the granulated particles after firing can be melted to improve surface irregularity and crystallinity, thereby improving fluidity. In this case, only the surface portion of the particles may be melted, however, the entire particle may be melted. The upper limit of the holding time in the above atmosphere is usually not more than several seconds (for example, not more than 3 seconds). This surface flattening treatment may be performed, for example, at a maximum temperature of about 3,000° C. in case of an oxygen burner in an in-flame treatment equipment, a maximum temperature of about 3,700° C. in case of a discharge plasma apparatus, or a maximum temperature of about 3,800° C. in case of a high-frequency induction thermal plasma apparatus, however, is not particularly limited. The particles after the surface flattening treatment may be classified so as to have a predetermined particle size, as needed.

Although the rare earth oxide thermal spraying material of the present invention has a smaller particle size compared with conventional rare earth oxide thermal spraying materials, they have high fluidity and can be thermal-sprayed even by an ordinary atmospheric plasma thermal spraying apparatus. By thermal spraying with using the rare earth oxide thermal spraying material of the present invention, a rare earth oxide thermal sprayed film having a low porosity, specifically a rare earth oxide thermal sprayed film having a porosity of not more than 1%, particularly not more than 0.9% can be obtained.

A rare earth oxide thermal sprayed film can be formed by thermal spraying, particularly plasma thermal spraying with using the rare earth oxide thermal spraying material of the present invention. The plasma thermal spraying may be suspension slurry plasma spraying (SPS), however, is preferably atmospheric plasma spraying (APS).

A rare earth oxide thermal sprayed film is usually formed on a base material to form a thermal sprayed member. A thermal sprayed member including a rare earth oxide thermal sprayed film formed with using the rare earth oxide thermal spraying material of the present invention is suitable as a member for a semiconductor manufacturing apparatus.

As materials for the base material, stainless steel, aluminum, nickel, chromium, zinc, their alloys, alumina, aluminum nitride, silicon nitride, silicon carbide, and quartz glass are exemplified. The rare earth oxide thermal sprayed film (thermal sprayed layer) can be formed so as to have a thickness of not less than 50 μm, particularly not less than 150 μm, especially not less than 200 μm, and not more than 500 μm.

Thermal spraying can be performed under normal pressure (atmospheric pressure) such as the atmospheric atmosphere, or under reduced pressure. As plasma gases, a mixed gas of nitrogen gas (N₂) and hydrogen gas (H₂), a mixed gas of argon gas (Ar) and hydrogen gas, a mixed gas of argon gas and helium gas (He), a mixed gas of argon gas, nitrogen gas and hydrogen gas, argon gas alone, nitrogen gas alone, and others are exemplified, and a mixed gas of argon gas and hydrogen gas is preferable, however, it is not particularly limited. Thermal spraying conditions may be appropriately set according to the base material, thermal spraying material and material of thermal sprayed film, application of the resulting thermal sprayed member, and others.

As a concreate example of thermal spraying, for example, in the case of argon/hydrogen plasma thermal spraying, atmospheric plasma thermal spraying using a mixed gas of 40 L/min of argon gas and 7 L/min of hydrogen gas is exemplified. Thermal spraying conditions such as a thermal spraying distance, a current value, and a voltage value are set according to the application of the thermal sprayed member. A predetermined amount of the thermal spraying material is filled in a powder supply apparatus, and a powder is supplied to the tip of a plasma spraying gun with a carrier gas (argon) with using a powder hose. By continuously supplying the powder into a plasma flame, the thermal spraying material is melted and liquefied, and turns into a liquid flame by force of plasma jet. When the liquid frame collides the substrate, the melted powder adheres, solidifies and deposits. Based on this principle, a thermal sprayed member (a coated part) can be produced by forming a thermal sprayed film (thermal sprayed layer) within a predetermined coating area on the substrate, while moving the flame left, right, up and down by a robot or human hand.

### EXAMPLES

To illustrate the invention in detail, Examples and Comparative Examples are given below, however, the invention is not limited by the following Examples.

### Examples 1 to 5

### [Production of Thermal Spraying Material]

As a raw material of rare earth oxide particles, in Examples 1 to 4, yttrium oxide (manufactured by Shin-Etsu Chemical Co., Ltd., Y2O3-UUHP, D50=0.1 μm) was used alone.

In Example 5, yttrium oxide (manufactured by Shin-Etsu Chemical Co., Ltd., Y2O3-UUHP, D50=0.1 μm), erbium oxide (manufactured by Shin-Etsu Chemical Co., Ltd., Er2O3-UUHP, D50=0.1 μm), and holmium oxide (manufactured by Shin-Etsu Chemical Co., Ltd., Ho2O3-UUHP, D50=0.1 μm) were mixed so as to be a ratio shown in Table 1 and used.

The rare earth oxide and carboxymethyl cellulose that were added into water were placed in a nylon pot containing 15 mmϕ nylon balls, and mixed for about 6 hours to obtain a slurry. The carboxymethyl cellulose was added so as to be 0.3 wt % with respect to the rare earth oxide. Concentrations of the rare earth oxide were set to 20 wt % in Examples 1 and 2, 10 wt % in Examples 3 and 4, and 30 wt % in Example 5, with respect to the total of the rare earth oxide and water.

Next, from the obtained slurry, granulated particles were obtained by granulating by a spray dryer (manufactured by Okawara Kakoki Co., Ltd., DBP-22, the same applies hereinafter) at a rotation speed of 23,000 rpm, firing in the air, and removing coarse particles by a sieve and fine particles by air classification.

Next, surface flattening treatment was subjected to the obtained granulated particles, at about 3,700° C. for 0.1 second by a discharge plasma apparatus (manufactured by AMT AG) in Examples 1 and 3, at about 3,600° C. for 0.1 second by a high-frequency plasma apparatus (manufactured by JEOL Ltd.) in Examples 2 and 5, and at about 2,900° C. for 0.2 seconds by an oxygen burner in an in-flame treatment equipment INFLAZ (manufactured by Chugai Ro Co., Ltd.) in Example 4, to obtain a thermal spraying material.

### [Evaluation of Physical Properties of Thermal Spraying Material]

Physical properties of the obtained thermal spraying material were evaluated. A particle size distribution (D10, average particle size D50, D90, D100) was measured by a laser diffraction method with using a particle size distribution analyzer (manufactured by MicrotracBEL Corp., MT3300EXII). A BET specific surface area was measured by a fully automatic specific surface area analyzer (manufactured by Mountec Co., Ltd., Macsorb HM model-1280). A tap density and a bulk density were measured by a powder tester (manufactured by Hosokawa Micron Corporation, PT-X) according to the JIS method, and a compression degree was calculated in accordance with the following expression:

Compression degree (%)=(tap density-bulk density)/tap density×100.

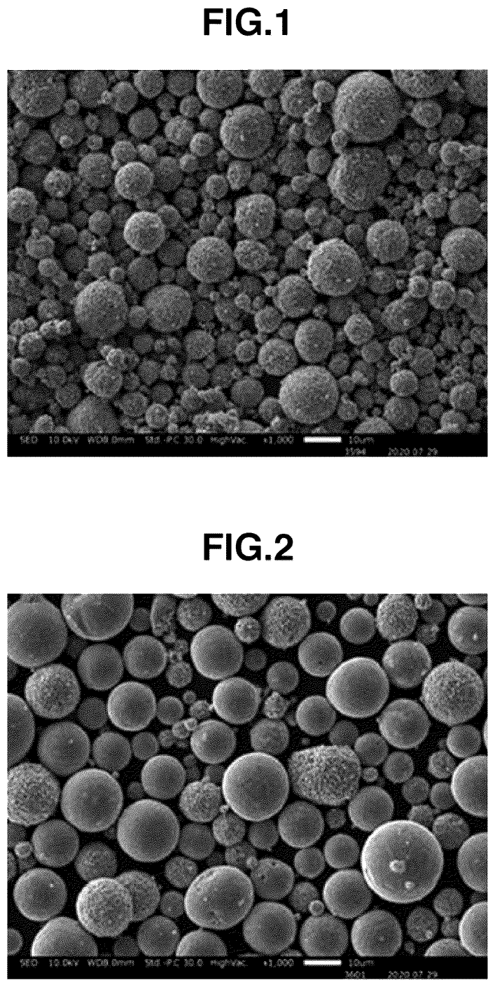

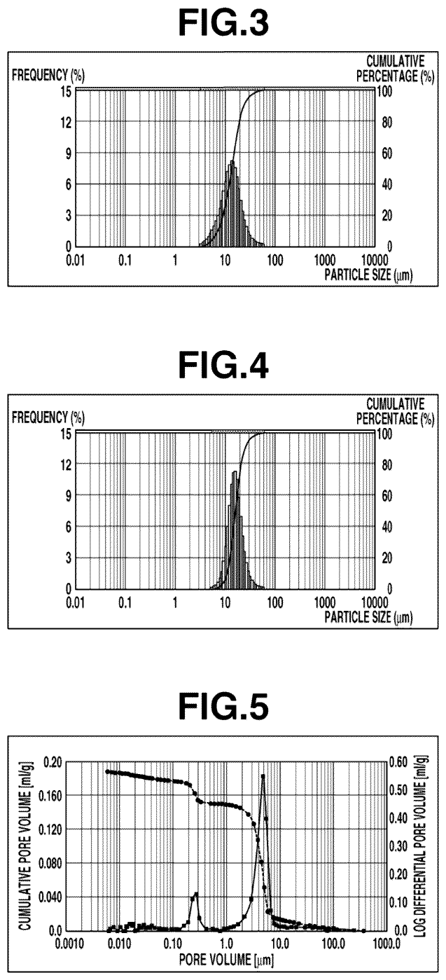

An angle of repose was measured by an injection method using a powder tester (manufactured by Hosokawa Micron Corporation, PT-X). A pore distribution was measured by a mercury intrusion method with using an automatic mercury porosimeter pore distribution measuring device (manufactured by Micromeritics Instrument Corporation, AutoPore III). A crystallite size was determined by analyzing crystal phases by an X-ray diffractometer (manufactured by PANalytical, X-Part Pro MPD, CuKα ray), and calculating by WPPD method (Whole-Powder-Pattern Decomposition method) within the range of 2θ=10 to 70°. The results are shown in Table 1. In addition, with respect to the particles before and after the surface flattening treatment of the thermal spraying material of Example 1, scanning electron microscope (SEM) images are shown in FIGS. 1 and 2, respectively, and charts of particle size distribution are shown in FIGS. 3 and 4, respectively. And, a chart of pore size distribution of the thermal spraying material of Example 2 is shown in FIG. 5.

### [Formation of Thermal Spray Film (Production of Thermal Sprayed Member)]

A thermal sprayed film having a thickness of about 200 μm was formed on the surface of an aluminum base material by atmospheric plasma spraying in which the obtained thermal spraying material was thermal-sprayed by a plasma spraying machine (manufactured by Oerlikon Metco, F-4) with using a mixed gas of argon gas and hydrogen gas, or a mixed gas of argon gas, hydrogen gas and nitrogen gas, as the plasma gas, to obtain a thermal sprayed member. The flow rates of the plasma gases, the applied electric power and the thermal spraying distance are shown in Table 2.

### [Evaluation of Physical Properties of Thermal Sprayed Film]

Physical properties of the obtained thermal sprayed film were evaluated. A film thickness was measured by an eddy-current coating thickness tester (manufactured by Kett Electric Laboratory Co. Ltd., LH-300). A surface roughness was measured by a surface roughness measuring instrument HANDYSURF (manufactured by Tokyo Seimitsu Co., Ltd., E-35A). A hardness (Vickers hardness HV) of the surface of the thermal sprayed film was measured 10 times by a micro Vickers hardness tester (manufactured by Shimadzu Corporation, HMV-G31-XY-S) under measurement conditions of HV 0.1 (980.7 mN) with holding for 10 seconds, and was evaluated as an average value of them. A porosity was measured by the method described later. The results are shown in Table 2.

### Comparative Examples 1 and 2

### [Production of Thermal Spraying Material, and Evaluation of Physical Properties of Thermal Spraying Material]

As a raw material of rare earth oxide particles, in Comparative Example 1, yttrium oxide (manufactured by Shin-Etsu Chemical Co., Ltd., Y2O3-UUHP, D50=0.1 μm) was used alone, and in Comparative Example 2, yttrium oxide (manufactured by Shin-Etsu Chemical Co., Ltd., Y203-UU, D50=0.1 μm) was used alone.

The rare earth oxide and carboxymethyl cellulose that were added into water were placed in a nylon pot containing 15 mmϕ nylon balls, and mixed for about 6 hours to obtain a slurry. The carboxymethyl cellulose was added so as to be 0.3 wt % with respect to the rare earth oxide. Concentrations of the rare earth oxide were set to 33 wt % in Comparative Example 1, and 40 wt % in Comparative Example 2, with respect to the total of the rare earth oxide and water.

Next, from the obtained slurry, granulated particles were obtained by granulating by a spray dryer at a rotation speed of 18,000 rpm, firing in the air, and removing coarse particles by a sieve and fine particles by air classification. In Comparative Examples 1 and 2, surface flattening treatment was not performed. Physical properties of the obtained thermal spraying material were evaluated in the same manner as in Examples. The results are shown in Table 1.

### [Formation of Thermal Spray Film (Production of Thermal Sprayed Member), and Evaluation of Physical Properties of Thermal Sprayed Film]

A thermal sprayed film having a thickness of about 200 μm was formed on the surface of an aluminum base material by atmospheric plasma spraying in which the obtained thermal spraying material was thermal-sprayed by a plasma spraying machine (manufactured by Oerlikon Metco, F-4) with using a mixed gas of argon gas and hydrogen gas, as the plasma gas, to obtain a thermal sprayed member. The flow rates of the plasma gases, the applied electric power and the thermal spraying distance are shown in Table 2. Physical properties of the obtained thermal sprayed film were evaluated in the same manner as in Examples. The results are shown in Table 2.

### [Measurement of Porosity]

A test piece of the thermal sprayed member was embedded in resin, a cross section was cut out, the cross section was mirror-finished (Ra=0.1 μm), and then a cross-sectional image (magnification: 200 times) was taken by a scanning electron microscope (SEM). After taking 10 fields of view (photographing area of 1 field of view: 0.017 mm²), image processing was performed by image processing software “Photoshop” (manufactured by Adobe Systems

Incorporated), and then porosity was quantified by image analysis software “Scion Image” (Scion Corporation), and an average porosity of 10 fields of view was evaluated in a percentage of the total image area.

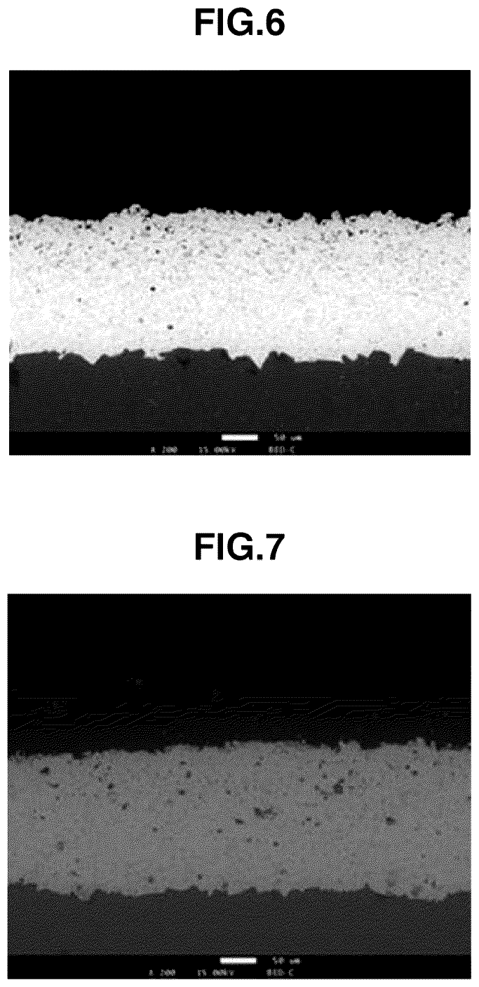

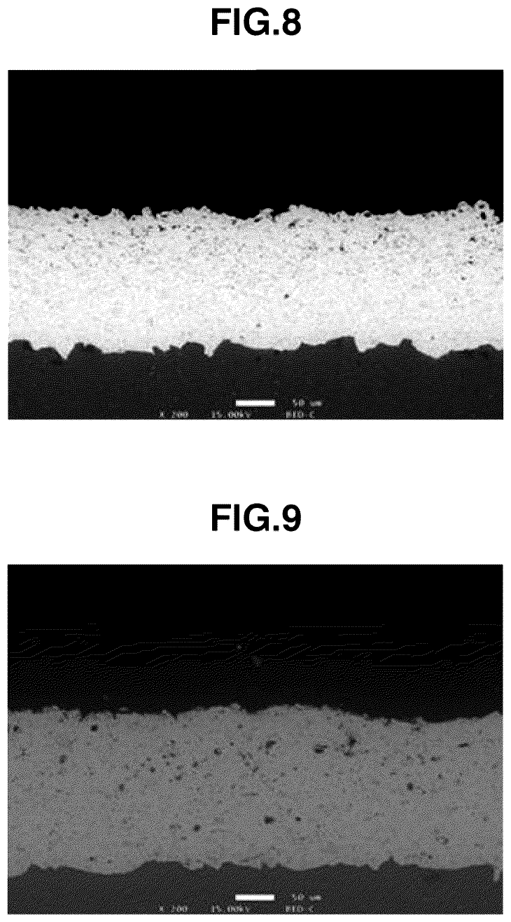

Scanning electron microscope (SEM) images of the cross sections of the thermal sprayed films of Example 1 and Comparative Example 1 are shown in FIGS. 6 and 7, respectively, and scanning electron microscope (SEM) images of the cross sections of the thermal sprayed films of Example 2 and Comparative Example 2 are shown in FIGS. 8 and 9, respectively. It can be seen that the thermal sprayed films obtained in Examples are dense thermal sprayed films having a lower porosity compared with the thermal sprayed films obtained in Comparative examples.

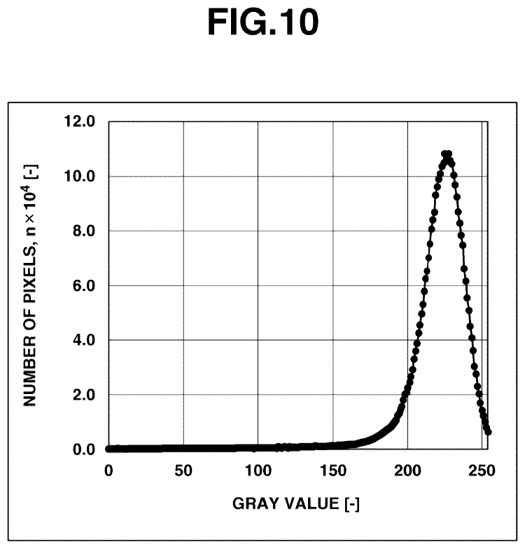

A cross-sectional image taken by an electron microscope is a backscattered electron image and is expressed in 8-bit grayscale. The cross-sectional image is expressed by light intensities (gray values) in 256 steps from 0 (no light state: black) to 255 (all light is maximally emitted) in each of pixels. In the cross-sectional image of the thermal sprayed film, void portion is in a state closer to black with respect to the entire thermal sprayed film, and has a relatively low gray value. A distribution of gray values of the scanning electron microscope (SEM) image of the cross section of the thermal sprayed film of Example 1 is shown in FIG. 10.

A threshold value was determined, and binarization processing was performed on the cross-sectional image of the thermal sprayed film. The gray values of the void portions are converted to 0, and the other gray values of the entire thermal sprayed film are converted to 255. A ratio of the total number of pixels of void portion to the total number of pixels in the cross-sectional image was defined as the porosity.

In the case that the threshold value is fixed in the binarization process, it is difficult to properly separate the voids since brightness and contrast are different in each image. Therefore, it is necessary to determine the threshold value according to brightness and contrast. In a general image binarization method, binarization is performed by setting a threshold value by focusing on valleys appearing in distribution of the gray value, and in this case, it is assumed that the distribution of the gray value is bimodal. However, as shown in FIG. 10, the gray values of the thermal sprayed film have a unimodal distribution, thus, a general method for binarization of image cannot be applied.

In the present invention, in order to quantify brightness and contrast, the distribution of the gray value was approximated by a normal distribution represented by the following expression. A gray value is represented by x, a number of pixels is represented by y, a maximum value of the normal distribution is represented by a, a gray value at the maximum value is represented by b, and a width of the normal distribution is represented by c. Fitting was performed by the non-linear least squares method, the gray value x was varied from 0 to 255, and the fitting parameters a, b, and c that are minimized the residual sum of squares of the number of pixels y in this were numerically analyzed by an iterative method. As initial values, a was set to 10,000, b was set to 100, and c was set to 10. As initial conditions, a was set to not less than 0, b was set to not less than 0 and not more than 255, and c was set to not less than 0.

$$y = a \times {e}^{\frac{{( x - b )}^{2}}{c}} \qquad [ Numerical expression 1 ]$$

The threshold value t was defined with the fitting parameters b and c of the normal distribution according to the following equation. This formula is a floor function, and integer part is applied as the threshold value. Since b corresponds to brightness and c corresponds to contrast, it means that the threshold value is determined according to brightness and contrast. When evaluating the thermal sprayed film of rare earth oxide, m was set to 4.93 and n was set to −114.29.

$$t = ⌊ b - \frac{c - n}{m} ⌋ \qquad [ Numerical expression 2 ]$$

TABLE 1

| | | | | | | | Comparative | Comparative |
|---|---|---|---|---|---|---|---|---|
| | | Example 1 | Example 2 | Example 3 | Example 4 | Example 5 | Example 1 | Example 2 |
| Rare earth oxide | | Y₂O₃ | Y₂O₃ | Y₂O₃ | Y₂O₃ | (Er_{0.8}Y_{0.1}Ho_{0.1})₂O₃ | Y₂O₃ | Y₂O₃ |
| Particle size | D50(μm) | 13.1 | 13.5 | 12.8 | 15.9 | 15.8 | 20.3 | 30.9 |
| distribution before | D10(μm) | 7.2 | 7.2 | 8.5 | 10.1 | 9.3 | 12.2 | 19.1 |
| surface flattening | D90(μm) | 23.3 | 23.7 | 21.0 | 26.2 | 24.0 | 35.5 | 49.3 |
| treatment | | | | | | | | |
| Method of surface | | Plasma | Plasma | Plasma | Flame | Plasma | — | — |
| flattening treatment | | | | | | | | |
| Particle size | D50(μm) | 15.3 | 16.1 | 13.6 | 18.1 | 17.4 | — | — |
| distribution after | D10(μm) | 10.7 | 10.9 | 9.1 | 13.0 | 11.0 | — | — |
| surface flattening | D90(μm) | 23.3 | 24.9 | 21.6 | 27.2 | 26.2 | — | — |
| treatment | D100(μm) | 62.2 | 62.2 | 52.3 | 62.2 | 69.3 | — | — |
| BET specific | m²/g | 0.3 | 0.5 | 0.7 | 0.2 | 0.4 | 4.6 | 2.9 |
| surface area | | | | | | | | |
| Tap density | g/cm³ | 2.71 | 2.33 | 2.30 | 2.48 | 2.87 | 2.56 | 2.69 |
| Bulk density | g/cm³ | 2.50 | 2.07 | 2.03 | 2.29 | 2.59 | 2.06 | 2.30 |
| Compression degree | — | 7.7 | 11.2 | 11.7 | 7.7 | 9.8 | 19.5 | 14.5 |
| Angle of repose | ° (deg) | 29.5 | 33.0 | 29.0 | 31.7 | 29.8 | 40.2 | 34.4 |
| Pore diameter at peak | μm | 4.5 | 4.8 | 4.2 | 6.1 | 5.7 | 7.2 | 10.7 |
| top of peak of large | | | | | | | | |
| pore diameter side | | | | | | | | |
| (First peak) | | | | | | | | |
| Cumulative pore | ml/g | 0.171 | 0.136 | 0.188 | 0.168 | 0.167 | 0.125 | 0.088 |
| volume (P1) of large | | | | | | | | |
| pore diameter side | | | | | | | | |
| (pore diameter of 1 to | | | | | | | | |
| 10 μm) | | | | | | | | |
| Pore diameter at peak | μm | 0.24 | 0.28 | 0.28 | 0.16 | 0.21 | 0.28 | 0.23 |
| top of peak of small | | | | | | | | |
| pore diameter side | | | | | | | | |
| (Second peak) | | | | | | | | |
| Cumulative pore | ml/g | 0.042 | 0.039 | 0.045 | 0.031 | 0.049 | 0.039 | 0.042 |
| volume (P2) of small | | | | | | | | |
| pore diameter side | | | | | | | | |
| (pore diameter of 0.1 to | | | | | | | | |
| 1 μm) | | | | | | | | |
| P2/P1 | — | 0.25 | 0.28 | 0.24 | 0.18 | 0.29 | 0.31 | 0.47 |
| Crystallite size | μm | 10 | 9.9 | 9.7 | 9.1 | 8.8 | 0.79 | 0.38 |

TABLE 2

| | | | | | | | Comparative | Comparative |
|---|---|---|---|---|---|---|---|---|
| | | Example 1 | Example 2 | Example 3 | Example 4 | Example 5 | Example 1 | Example 2 |
| Thermal spraying machine | | F-4 | F-4 | F-4 | F-4 | F-4 | F-4 | F-4 |
| Gas flow rate Ar | L/min | 40 | 40 | 40 | 40 | 40 | 40 | 40 |
| Gas flow rate H₂ | L/min | 7 | 7 | 7 | 5 | 9 | 7 | 7 |
| Gas flow rate N₂ | L/min | 0 | 0 | 0 | 2 | 0 | 0 | 0 |
| Electric power | kW | 32 | 32 | 32 | 32 | 32 | 32 | 32 |
| Thermal spraying | mm | 120 | 120 | 120 | 120 | 120 | 120 | 120 |
| distance | | | | | | | | |
| Film thickness | μm | 200 | 206 | 199 | 214 | 226 | 207 | 235 |
| Surface roughness | Ra (μm) | 4.11 | 3.63 | 3.73 | 3.58 | 3.83 | 4.55 | 5.50 |
| Surface hardness | HV | 501 | 502 | 508 | 514 | 508 | 495 | 485 |
| Porosity | % | 0.78 | 0.86 | 0.78 | 0.85 | 0.84 | 1.21 | 2.23 |

1. A rare earth oxide thermal spraying material having a volume-based average particle size D50 by a laser diffraction/scattering method of not less than 10 μm and not more than 18 μm, a compression degree of not more than 13, and a BET specific surface area of not less than 0.1 m²/g and not more than 2 m²/g.

2. The rare earth oxide thermal spraying material according to claim 1, wherein, in a pore volume distribution measured by a mercury intrusion method, the pore volume distribution has a first peak within a range of pore diameter of 1 μm to 10 μm, and a second peak within a range of pore diameter of less than 1 μm, and a ratio (P2/P1) of a cumulative pore volume (P2) within a range of pore diameter of 0.1 μm to 1 μm to a cumulative pore volume (P1) within a range of pore diameter of 1 μm to 10 μm is not less than 0.05 and not more and 0.3.

3. The rare earth oxide thermal spraying material according to claim 1, wherein a crystallite size calculated from a peak of a rare earth oxide measured by X-ray diffraction is not less than 1 μm.

4. The rare earth oxide thermal spraying material according to claim 1, wherein a rare earth element constituting the rare earth oxide comprises at least one selected from yttrium (Y), gadolinium (Gd), holmium (Ho), erbium (Er), ytterbium (Yb) and lutetium (Lu).

5. A producing method of a particulate rare earth oxide thermal spraying material having a volume-based average particle size D50 by a laser diffraction/scattering method of not less than 10 μm and not more than 18 μm, comprising:
a step for preparing a slurry comprising rare earth oxide particles and a dispersion medium;
a step for obtaining granulated particles in which the rare earth oxide particles are agglomerated from the slurry;
a step for firing the granulated particles at a temperature of not less than 1400° C. and not more than 1600° C.; and
a step for holding the granulated particles after firing under an atmosphere having a temperature of not less than 2,400° C. and not more than 3,900° C. for not less than 0.1 second to melt at least a surface portion of each of the granulated particles after firing, and then taking out from the atmosphere and cooling.

6. A rare earth oxide thermal sprayed film which is formed by atmospheric plasma spraying with using the rare earth oxide thermal spraying material according to claim 1, and has a porosity of not more than 1%.

7. A forming method of a rare earth oxide thermal sprayed film, comprising forming by atmospheric plasma spraying with using the rare earth oxide thermal spraying material according to claim 1.

8. The forming method according to claim 7, wherein a rare earth oxide thermal sprayed film having a porosity of not more than 1% is formed.
